(19) United States
(12) Patent Application Publication
(10) Pub. No.: US 2014/0001578 A1
(43) Pub. Date: Jan. 2, 2014

(54) GAS PRESSURE MEASUREMENT CELL ARRANGEMENT

(71) Applicants: Urs Walchli, Chur (CH); Bruno Berger, Haag (CH); Daniel Vogel, Trubbach (CH)

(72) Inventors: Urs Walchli, Chur (CH); Bruno Berger, Haag (CH); Daniel Vogel, Trubbach (CH)

(73) Assignee: INFICON GMBH, Bad Ragaz (CH)

(21) Appl. No.: 14/004,458

(22) PCT Filed: Feb. 10, 2012
(86) PCT No.: PCT/CH2012/000038

§ 371 Date: Sep. 11, 2013

(30) Foreign Application Priority Data
Mar. 30, 2011 (CH) 577/11

(51) Int. Cl. H01L 29/84

(52) U.S. Cl. CPC H01L 29/84
USPC 257/415

(57) ABSTRACT

A gas pressure measuring cell configuration has a thermal conduction vacuum cell according to Pirani (Pi), with a measuring chamber housing enclosing a measuring chamber and with a measuring connection which channels the gas pressure P to be measured into the measuring chamber. The measuring chamber has a heatable measuring filament connected to an electronic measuring circuitry. The electronic measuring circuitry is in thermal contact on one side of an insulating carrier plate and the carrier plate forms on the opposite side a component of the measuring chamber housing, wherein the measuring filament in series with a measuring resistor (Rm) is supplied directly by the electronic measuring circuitry in feedback and wherein the electronic measuring circuitry directly determines the resistance of the measuring filament.

The invention relates to a gas pressure measuring cell configuration according to the preamble of Patent Claim 1.

It is known to employ gas pressure measuring cells that are implemented as thermal conduction measuring cells, for example according to Pirani. In such measuring cells a heating element, conventionally a measuring filament or measuring wire, is heated electrically, and from the filament power the pressure of the gas is determined via the pressure-dependence of the thermal conductivity of the gas. In this manner the pressure can be measured in a range between approximately 10⁻⁴ mbar and a few 100 mbar. However, above a few 10 mbar the convective heat transfer predominates such that the measurement of gas flow is affected and becomes highly position-dependent. In addition, measurement according to this method is gas-type dependent. Analysis of the measuring signal with electronic measuring circuitry is relatively complex if precise results over a broad range are to be attained. This is especially the case toward higher pressures starting at approximately 10 mbar since at this pressure the measuring curve, filament power as a function of gas pressure, levels out at constant heating filament temperature. One reason inter alia is also the fact that in this pressure range, as previously indicated, the effect of the flow regime of the gas increases. As is known, the measuring circuitry utilized for this purpose is realized with a Wheatstone-bridge configuration in which one of the four bridge resistances is determined by the measuring filament. Regulation of the measuring filament temperature and analysis of the signal voltage output by the bridge is carried out using measuring electronics, conventionally in analog circuit technology, which, in known manner, comprises for example operational amplifiers and/or comparators. Due to the high temperature sensitivity of the measuring configuration, the temperature of the measuring configuration must additionally be acquired as a reference and also be taken into consideration with the measuring electronics. Such Pirani type gas pressure measuring cells are sensitive and therefore relatively complex and expensive in their realization. However, they are currently in wide use. An overview of this measuring technique is described for example in M. Wutz et al. “Theorie and Praxis der Vakuumtechnik”, F. Vieweg & Sohn, Braunschweig, 1982, 2^{nd} Edition, pp. 366-373.

Such a product has been distributed worldwide for many years with great success by INFICON GmbH, FL-9496 Balzers, Liechtenstein under the product identification Series PSG 50X.

To expand the pressure range to be measured it has also been proposed to combine such a Pirani measuring cell with at least one further different measuring principle. Herewith the pressure range to be measured can be expanded in the lower range as well as the upper range such that it becomes feasible, for example, to realize a combination measuring cell which can measure pressures in the range of 10⁻⁸ mbar up to a few bar. Such a combination measuring cell is described, for example, in EP 0 658 755 B1 which combines on a common measuring head a Pirani sensor with an ionization sensor. This document also describes the manner in which the overlapping regions can be handled in terms of signal technology in order to ensure a continuous and linear transition in the signal analysis.

EP 1 097 361 B1 describes a further combination measuring cell in which a Pirani sensor is combined with a capacitive membrane sensor (CDG). In this document directions are also provided for improving the manner in which the problems of temperature control, always inherent in the Pirani measuring principle, can be improved through measures on the sensor head.

Known is also the use of piezoresistive pressure sensors based on semiconductors for acquiring the pressures, especially in the range from 1.0 mbar to 1.0 bar, or even a few bar up to approximately 3.0 bar. Such pressure sensors are suitable for the upper pressure range. Such a pressure sensor is for example described in M. Wutz et al. “Theorie and Praxis der Vakuumtechnik”, F Vieweg & Sohn, Braunschweig, 2010, 10^{th} Edition, pp. 513-514. In such sensors onto a semiconductor membrane are for example applied doped, low-ohmic conductor tracks which form resistances. The resistances are connected such that they form a bridge. For reading out the signal the bridge terminals are carried to the outside. A change of the gas pressure on the membrane causes a deformation of the semiconductor membrane and, from the resistance change resulting therefrom, to the detuning of the bridge. Silicon is especially suitable as the semiconductor material since it is highly flexible. In such semiconductor resistances a pressure change in the material causes a resistance change which is analyzed as pressure mass. Semiconductor materials are especially suitable since not only the resistance changes in them due to the change of the geometric dimensions but additionally its specific resistance whereby additionally the piezoresistive effect is also reinforced. Moreover, the conventional four resistances can be disposed on the membrane such that all effect a signal change in the desired direction during the membrane flexure. This leads to good signal levels. In addition, this configuration also enables integrating, as desired, directly further active components, such as amplifiers or digital elements. Suitable piezoresistive pressure sensors based on silicon are distributed, for example, by Measurement Specialities, 1000 Lucas Way, Hampton, Va. 23666, USA.

The disadvantages of prior art with respect to a Pirani measuring cell and of combination measuring cells when reduced to practice are entailed in the complexity of the configuration with its large number of necessary components. Such a measuring cell requires a vacuum lead-through which separates the vacuum with the sensor cleanly and over long periods of time at high quality during different applications and temperature conditions against atmosphere toward the electronic measuring circuitry. Such vacuum lead-throughs always represent a temperature barrier which hinders the necessary measures for temperature measurements and temperature compensations and thus make them complicated. This also affects negatively the overall size, and smaller measuring cells are only conditionally realizable and the production costs cannot be further reduced.

The present invention addresses the elimination of the disadvantages of prior art. In particular, the present invention addresses the problem of significantly simplifying the structure of a Pirani gas pressure measuring cell configuration while simultaneously attaining a smaller overall size at an increase of the economy of production. This is to be attained without decreasing the measuring quality compared to known measuring cells. This quality is preferably to be improved further. An additional task comprises enabling the expansion of the measuring range of the Pirani measuring cell without the necessity for major additional expenditures.

This problem is resolved in the generic gas pressure measuring cell configuration according to the characterizing features of patent claim 1. The dependent patent claims refer to advantageous further embodiments of the invention.

The gas pressure measuring cell configuration according to the invention comprises a thermal conduction vacuum cell after Pirani comprising a measuring chamber housing which encloses a measuring chamber and which conducts the gas pressure to be measured into the measuring chamber using a measuring connection. In the measuring chamber is disposed a heatable measuring filament connected to an electronic measuring circuitry, with the electronic measuring circuitry being disposed in thermal contact on one side of an insulating carrier plate, preferably comprised of ceramics, and this carrier plate on the opposite side being a portion of the measuring chamber housing. The measuring filament is supplied in series with a measuring resistance directly in feedback by the electronic measuring circuitry and the electronic measuring circuitry determines directly the resistance of the measuring filament.

For measuring the voltages required for this purpose they are supplied to an analog/digital converter ADC and treated in a digital processor for their processing according to specified algorithms. The processor, in turn, conducts necessary signals out via a digital/analog converter DAC for driving and heating the measuring filament of the Pirani configuration which closes the feedback control circuit. The processed signal, in addition, is conducted out by the processor via an I/O interface for further utilization. This interface is preferably implemented as a serial interface. If it is desired to make other types of signals available, such as in parallel or even analog, this is feasible in simple manner using additional electronic circuitry integrated on the carrier plate. Omitting the conventional lead-through and employing the previously described carrier plate, which is preferably comprised of ceramics, as a substrate yields unexpected advantages in the overall temperature behaviour of the gas pressure measuring cell configuration and also unexpectedly novel mounting options for further structural component parts.

For the expansion of the measurable pressure range it is especially advantageous to tie directly into the electronic measuring circuitry on the carrier plate a piezoresistive semiconductor pressure sensor which thereby is also thermally coupled directly with the carrier plate. The present construction also enables connecting in simple manner the piezoresistive pressure sensor directly via a small port in the carrier plate such that it communicates with the measuring chamber in which the measuring filament is also disposed. Such a piezoresistive pressure sensor can advantageously not only be used for pressure measurements alone but also simultaneously for temperature measurements.

The processor based electronic circuitry also entails the significant advantage that it is feasible to work with lower total voltages since there is no longer a need for a bridge circuit. It is also not necessary to select the measuring resistance in the same dimension as the measuring filament. The utilized feed voltage can now be in the low range of approximately 2.0 to 5.0 V and it is even feasible to work pulse-free. In this case the temperature of the measuring filament can now be selected in broad ranges and also be set such that it is variable as a function of pressure in order to circumvent selectively, for example, contamination-sensitive regions or alternatively be better able to manage them. This combined gas pressure measuring cell configuration is extremely simple and cost-effectively realizable at high measuring accuracy and service life. The measuring range to be covered that is feasible and advantageous therewith extends from vacuum to atmosphere pressure, from approximately 10⁻⁴ mbar to 3,000 bar, preferably from 10⁻³ mbar to 2,000 bar at a resolution of better than 30%, preferably better than 15%, in particular better than 5% of the particular measured measurement value.

The invention will be described below schematically and by example in conjunction with Figures.

In the drawing depict:

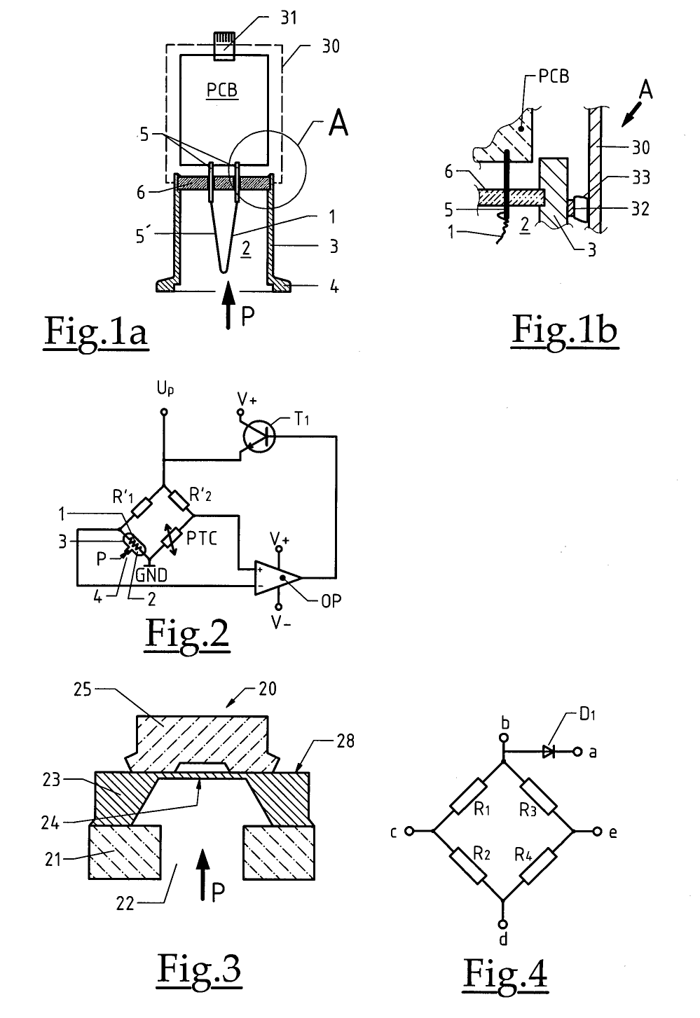

FIG. 1a schematically and in cross section a gas pressure measuring configuration of the type of thermal conduction vacuum meter after Pirani according to prior art;

FIG. 1b schematically and in cross section an enlarged detail A of a portion of the measuring cell according to FIG. 1a;

FIG. 2 the electric circuit in fundamental principle for a Pirani measuring cell such as is shown for example in FIGS. 1a and 1b;

FIG. 3 schematically and in cross section an example of a piezoresistive semiconductor pressure sensor;

FIG. 4 the fundamental circuit diagram of the piezoresistive pressure sensor according to the implementation after FIG. 3;

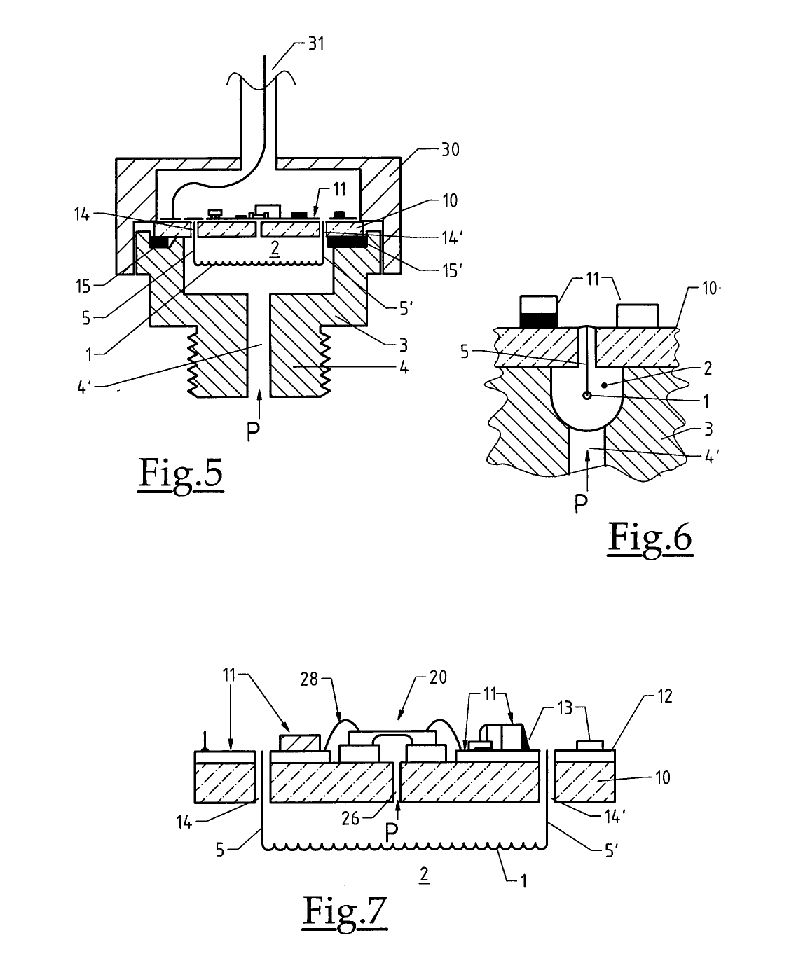

FIG. 5 schematically and in cross section a gas pressure measuring cell configuration according to the present invention;

FIG. 6 schematically and in cross section a detail depiction from FIG. 5 with depiction of the measuring chamber and carrier plate disposed thereon;

FIG. 7 schematically and in cross section a further development of the gas pressure measuring configuration according to the present invention, additionally in combination with a piezoresistive pressure sensor;

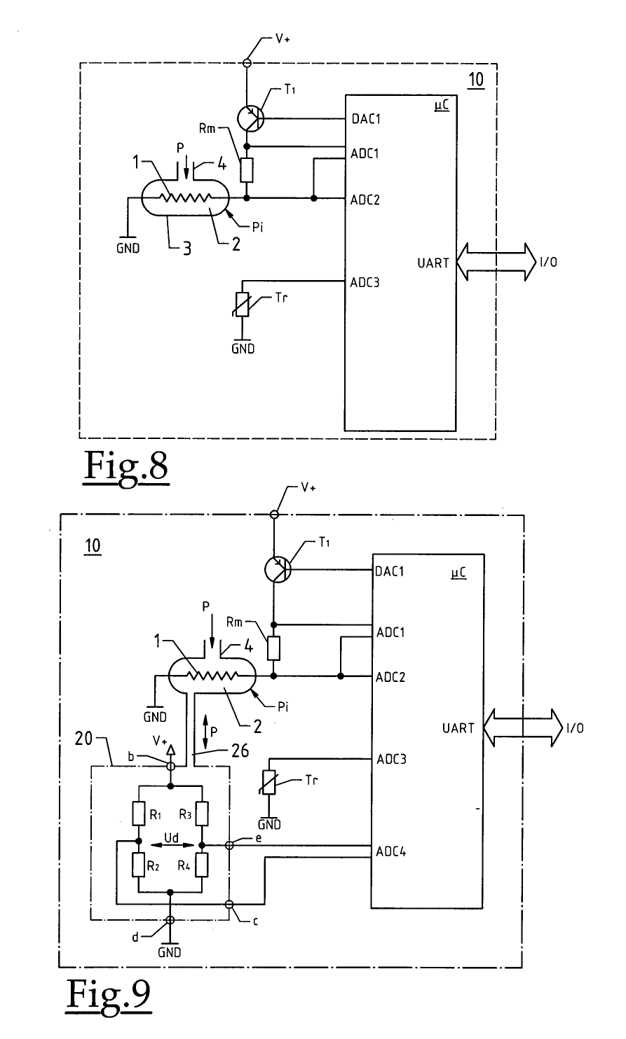

FIG. 8 circuit configuration with Pirani measuring cell according to the present invention;

FIG. 9 circuit configuration with Pirani measuring cell according to FIG. 8, additionally in combination with a piezoresistive pressure sensor according to the present invention;

FIG. 10 circuit configuration according to FIG. 9 with reference temperature measurement across the piezoresistive pressure sensor;

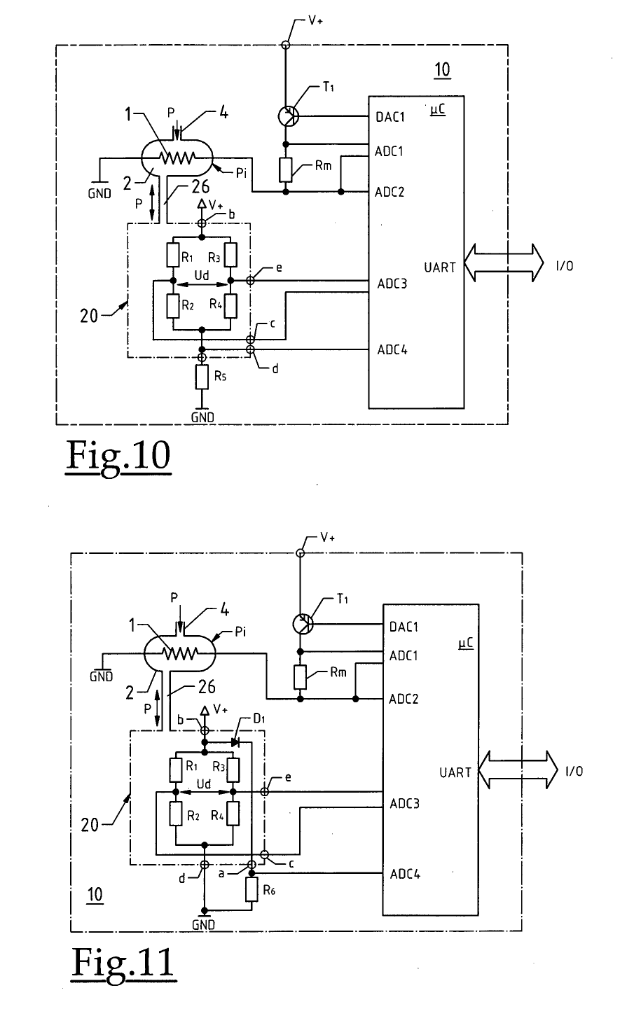

FIG. 11 circuit configuration according to FIG. 9 with reference temperature measurement across the internal diode of the piezoresistive pressure sensor.

A known measuring cell configuration of the type of thermal conduction vacuum cell after Pirani is shown schematically and in cross section in FIG. 1a. A measuring chamber 2 contains a measuring filament 1, which, via a lead-through body 6, 5 and tight-vacuum technology, is suspended electrically insulated. The measuring filament is retained, for example, by two mounting pins 5, and extension 5′ which lead electrically through the insulating body of the lead-through 6 to the electronic measuring circuitry located outside of the measuring chamber 2. The electronic circuitry of the electronic measuring circuitry is disposed in known manner on a printed circuit board PCB. The measuring chamber 2 is enclosed by the measuring chamber housing 3 and forms the chamber wall. On one side the measuring chamber 2 is open and accessible and can optionally be connected to the vacuum volume and the vacuum pressure P to be measured therein, for example via a flange-like portion of the measuring chamber housing 3, which therewith forms the measuring connection 4 with measuring port 4′. A housing 30 encloses the electronic measuring circuitry PCB which is connected to the peripheral analysis units and/or controls via a cable or a plug 31. Such a gas pressure measuring cell configuration consequently forms a measuring cell that can be modularly employed.

With the electronic measuring circuitry disposed on the printed circuit board PCB the Pirani measuring principle is operated. In this case the measuring filament 1, as a component of a Wheatstone bridge R₁′, R₂, PTC, is maintained at constant temperature as is depicted schematically in FIG. 2 in a circuit diagram. The power that must be applied to maintain the temperature at a constant is subsequently a measure of the measurement gas pressure P surrounding the filament. The measuring voltage is tapped through an operational amplifier or comparator OP at one diagonal of the Wheatstone bridge and the output signal is fed back, for example via integrated circuit or transistor T1, as bridge operating voltage connected to the second bridge diagonal. A similar circuit is described for example in M. Wutz et al. “Theorie and Praxis der Vakuumtechnik”, F. Vieweg & Sohn, Braunschweig, 1982, 2^{nd} Edition, Page 369. Depending on the design of the circuit, it is possible to operate in known manner with constant wire temperature of the measuring filament 1 or with constant filament power.

In a branch of the Wheatstone bridge in known manner a temperature sensor is installed, such as for example a PTC or an NTC, to acquire the ambient temperature and to reference to it. The measuring configuration is highly temperature sensitive and varying ambient temperatures affect the measurement and would generate measuring errors unless they are compensated. Good temperature measurement and compensation is therefore very important in Pirani thermal conduction measuring cells. The temperature sensor must therefore also be disposed at a suitable location in order to be able to acquire the critical temperature changes as characteristically as possible. A disposition of such a temperature sensor 32 in practice is depicted in FIG. 1b, which represents an enlarged detail A of FIG. 1a. The temperature sensor 32, for example a PTC resistance, is here pressed at the upper end region of measuring chamber housing 3, in the proximity of a lead-through 6, from the outside onto its wall using a resilient element 33 such that here, between measuring chamber housing 3 and the temperature sensor 32, good thermal contact is attained. The resilient element 33 can be formed for example of the PCB material itself if this printed circuit PCB itself is formed as a flexprint material. The connection is therewith detachable and electrically insulated through the flexprint. The temperature sensor 32 with the resilient element 33 in the depicted example is disposed between the slid-over protective housing 30 and the measuring chamber housing 3 such that the connection is detached simply when the protective housing is pulled off. This type of implementing electrical contact is relatively complex and expensive since this connection must be electrically insulating and, in the most favorable case, for example for a sensor exchange, must be detachable.

For measuring higher gas pressures in the vacuum range of approximately 1.0 mbar to 1.0 bar measuring sensors 20 have also become known which operate according to the piezoresistive principle, such as has previously been explained above. Such a sensor is depicted for example schematically and in cross section in FIG. 3. In a semiconductor wafer 23, preferably of silicon, at one zone an indentation has been rendered out which zone is sufficiently thin and thereby forms a membrane 24 which can deflect according to the applied pressure P to be measured. On this membrane doped, low-ohmic conductor tracks are applied forming the measuring resistances, the values of which change with deflection. The electrical lead-outs 28 of these measuring resistances R1 to R4 enable the signal processing by electronic measuring circuitry. This silicon component 23, together with the membrane 24, forms the silicon pressure sensor 23, 24 and is mounted on a base plate 21 as a support which comprises an access port 22 leading the measurement gas pressure P to be measured to the membrane 24. On the backside of the silicon pressure sensor 23, 24 a cover plate 25 with a hollow volume is disposed for protection over the membrane 24. The base plate 21 and the cover plate 25 are preferably comprised of glass. In FIG. 4 the fundamental electric circuit diagram is depicted. The measuring resistances R1 to R4 are wired in bridge connection and their terminals b to e are led out. Depicted is also that the internal diode D1, which the semiconductor forms through the doping, can be led out electrically separately at terminal a.

A gas pressure measuring cell configuration with a thermal conduction vacuum cell after Pirani according to the present invention is depicted schematically and in cross section in FIG. 5. The measuring chamber housing 3 encloses a measuring chamber 2 and includes a measuring connection 4 with a port 4′ which conducts the gas pressure P to be measured into the measuring chamber 2. Within the measuring chamber 2 a heatable measuring filament 1, preferably comprised of a metal such as tungsten, is disposed which is connected to electronic measuring circuitry 11. The electronic measuring circuitry 11 is disposed such that it is in thermal contact on one side of a ceramic carrier plate 10. On the opposite side of the electronic measuring circuitry 11 the carrier plate 10 forms a portion of the measuring chamber housing 3. The carrier plate 10 consequently seals the measuring chamber 2 such that it is vacuum-tight. The measuring filament 1 is connected in series with a measuring resistor Rm and is supplied by the electronic measuring circuitry directly in feedback, preferably within a feedback control circuit, with the electronic measuring circuitry 11 determining the resistance of the measuring filament 1 immediately and directly. The carrier plate 10 is comprised of an insulating material such as ceramics, preferably of an aluminum oxide ceramic. This ceramic has higher thermal conductivity than, for example, glass. This is important in order to enable maintaining good control over the temperature behavior of the configuration. A typical lead-through glass has, for example, a thermal conductivity of only approximately 1 W/(mK), whereas the cited aluminum oxide ceramic has approximately 25 W/(mK). The temperature measurement for determining the reference temperature can now be carried out directly on the carrier plate 10 itself or is a component of the electronic circuit applied on the carrier plate 10. For that purpose separate temperature sensors, such as semiconductor sensors or other types, can be provided on the carrier plate within the electronic circuitry or suitable circuit elements of the electronic measuring circuitry itself can even be employed to this end.

The carrier plate 10 can advantageously be implemented as a separate structural unit and be mounted vacuum-tight with a seal 15, 15′ on the measuring chamber housing 3. This seal can be, for example, an elastomer seal and be implemented as an O-ring 15 or as a flat seal 15′ or it can also be implemented as a metal seal. In certain cases, however, it can also be fixedly mounted on the measuring chamber housing 3, for example through sintering, soldering, etc. However, it is especially advantageous if the carrier plate 10 is simply adhered vacuum-tight onto the measuring chamber housing 3. The present novel construction according to the invention enables the use of robust low-outgassing adhesives since the involved components now have similar thermal coefficients which prevents stress micro-fractures from forming.

The carrier plate 10 is advantageously formed in the shape of a disk. Through the mentioned disposition the lead-through and the sensor retainer (measuring filament) are now combined in a single element and simultaneously the electronic measuring circuitry is also integrated.

The measuring filament 1 comprises at both ends support pin-like filament connections 5, 5′. On the carrier plate two inlet ports 14, 14′ are provided which receive the support pins 5, 5′ and which pins are connected with the electronic circuit 11 on the other side of the carrier plate 10. For this purpose the inlet ports 14, 14′ are advantageously contacted-through in a way similar to that known from printed circuit boards. However, this type of through-contacting must also be capable of withstanding higher temperatures and must be vacuum capable and thus tight. This requires a sintering process in the production. The configuration can be structured highly compactly. It is herein advantageous if the measuring filament is disposed approximately parallel to the surface of the carrier plate 10 as is shown in the example of FIGS. 5 and 6. In this disposition it is, for example, sufficient if in the measuring chamber housing 3 a simple groove-shaped recess is implemented which forms the measuring chamber 2 for receiving the measuring filament 1. The measuring chamber housing 3 is advantageously comprised of a metal such as, in particular, Inox. The region of the carrier plate 10 with the electronic measuring circuitry 11 can be protected with a protective housing 30 and for the electric connection of the measuring cell cables 31 and/or plugs can be provided as is conventionally the case.

The electronic measuring circuitry is applied directly on the insulating carrier plate 10. The conductor tracks are in direct contact with the surface of the carrier plate 10 on which the electronic components 13 are also integrated and/or disposed. The disposition of the conductor tracks 12 with the electronic components 13 takes place using techniques known per se such as are employed, for example, for printed circuits (PCB), thin film circuits or also thick film circuits. The thick film circuit technique is herein especially suitable. This is also compatible with the preferred ceramic as the carrier plate 10. It is also of advantage if the surface roughness of the carrier plate is lower than 0.6 μm. In thick film technique the conductor tracks 12 and any insulating layers are applied using screen printing and subsequently burnt-in or sintered. The electronic components are subsequently mounted, for example by soldering or bonding. The circuit can also be implemented in known manner as a hybrid circuit. In such circuits, for example, resistances are implemented as a component of the conductor track 12 and further structural elements 13, such as active structural elements, are mounted on the conductor tracks 12. The structural elements 13 mounted on the conductor tracks 12 are preferably and at least to some extent implemented using surface mounted device (SMD) techniques.

The carrier plate 10 can have a thickness in the range of 0.5 mm to 5.0 mm, preferably in the range of 0.6 mm to 2.0 mm. This is especially advantageous if aluminum oxide ceramic is utilized as the material for the carrier. The diameter of the carrier plate 10 is herein within a range of 10.0 mm to 50.0 mm, preferably in a range of 15 mm to 35 mm. The measuring filament 1 is implemented as a metal coil, preferably of tungsten or nickel, and has a filament length from pin 5 to pin 5′ in the range of 10.0 mm to 40.0 mm, preferably in the range of 12.0 mm to 25 mm.

The entire measuring cell can therewith be built very small with a diameter in the range of only 14 mm to 54 mm, preferably 19 mm to 39 mm, with the height without cable tap being in the range of 15 mm to 40 mm. The connection flange can be implemented, for example, as threading, such as for example with ⅛″ threading.

The electronic measuring circuitry includes a processor (μC) for the digital processing of the measured signals and control of the measuring filament 1 as is shown in the circuit diagram of FIG. 8. The measuring filament 1 of the Pirani measuring cell Pi is supplied across a digital/analog converter (DAC1) under control wherein for the power tuning for example a driver is provided, such as for example a transistor T1 or an integrated circuit.

The measuring resistor Rm is connected in series with the measuring filament 1 and is disposed between the driver T1 and the measuring filament 1. The signal at the measuring resistor Rm and at the measuring filament 1 is tapped and supplied across one analog/digital converter (ADC1, 2) to the processor (μC) for further processing. Hereby the feedback circuit is formed across which the filament power is controlled and/or regulated according to the programmed specifications. According to the programmed specified algorithms the gas pressure to be measured is determined with the processor and transmitted to the I/O interface for further analysis or further processing to the periphery. In addition, with a temperature sensor Tr disposed in the circuit configuration on the carrier plate 10, the reference temperature at this site is determined and its signal is also supplied to the processor across an analog/digital converter (ADC3) such that the programmed processor can determine the suitable correction measures and include them. The configuration with the direct measurement and regulation via a processor also enables the temperature of the measuring filament 1 as a function of the measured conditions to be now freely selectable and settable.

The above concept can be readily equipped with further additional electronic components should this be required and desired. It is, for example, especially advantageous for the circuit configuration on the carrier plate to be supplemented by a further electronic component, that is to say by a piezoresistive pressure sensor 20 on semiconductor base, as is shown schematically and in cross section in FIG. 7. This type of pressure sensor has a very small overall size, for example of approximately 1.0 to 2.0 mm² which permits it to be incorporated simply into the present concept of the circuit configuration on the carrier plate 10 similar to an SMD structural component. The geometric dimension of the measuring cell configuration is thereby also only minimally affected. The piezoresistive pressure sensor 20 is advantageously disposed by vacuum-tight adhesion on the carrier plate 10 on the side of the conductor track and its electric terminals 28 (a-d) are here electrically connected with the associated conductor tracks. The adhesive agent is advantageously a silicon adhesive.

The piezoresistive semiconductor pressure sensor 20 comprises preferably a silicon membrane 24. In the carrier plate 10 a port is provided as a connection duct 26 which connects the measuring chamber 2 with the piezoresistive pressure sensor 20 such that they communicate. The piezoresistive pressure sensor 20 is consequently oriented on the carrier plate such that its access port 22 is connected as the measuring port directly with the connection duct 26 located in the carrier plate 10 such that they communicate and thereby the connection to the measuring chamber 2 is established in which the measuring filament 1 is also disposed. The signal output of the piezoresistive pressure sensor 20 is connected across a further ADC (ADC4) with the processor for its direct signal analysis as is shown in the circuit diagrams in FIGS. 9 to 11. Terminals c and e on the piezoresistive pressure sensor tap the pressure signal Ud of the piezoresistive bridge and it is carried across an ADC (ADC4) to the processor, and across terminals b and d this bridge is electrically supplied via V+ and Gnd. With V⁺ in each case is indicated, in known manner, the supply voltage, and with Gnd, “ground” or chassis earth connection. As in FIG. 8, FIG. 9 also shows a temperature sensor which can be the component of the circuit configuration on the carrier plate 10 in order to acquire the reference temperature and supply it to the processor as a signal across an ADC (ADC3).

A further advantageous feasibility of acquiring the reference temperature comprises measuring the temperature coefficient of the piezoresistive pressure sensor 20 directly and acquiring it, for example, via a resistor R5 connected between terminal d of the bridge and Gnd, as is shown by example in FIG. 10. The temperature signal tapped at resistor R5 is subsequently again supplied across an ADC (ADC4) to the processor and here processed. In this case a separate temperature sensor Tr can be omitted.

A further, still more advantageous feasibility for measuring the reference temperature comprises utilizing the temperature coefficient of the internal diode D1 of the semiconductor junction of the piezoresistive pressure sensor 20. The terminal of diode D1 is led out at point a and connected to Gnd across a resistor R6 as is depicted by example in FIG. 11. The temperature signal tapped at resistor R6 is subsequently again supplied across an ADC (ADC4) to the processor and here processed. In this case a separate temperature sensor Tr can also be omitted. This type of temperature measurement is especially simple and precise. In addition, the measuring site is located directly in the semiconductor material of the piezoresistive pressure sensor 20.

With the introduced combined gas pressure measuring cell configuration the two measuring principles, a Pirani thermal conduction manometer and a piezoresistive pressure sensor, are according to the present invention optimally combined with one another. The measuring ranges of the two measuring principles overlap and with the introduced electronic signal analysis a large pressure range to be measured for gas pressures can now be covered continuously and with high measuring precision. The Pirani configuration Pi can preferably cover a range from 10⁻³ mbar to a few 100 mbar and the piezoresistive pressure sensor 20 a range of 1 mbar to 2.0 bar. Consequently, the entire preferably coverable measuring range lies at gas pressures in the range from 10⁻³ mbar to 2.0 bar at sufficiently high precision. In certain cases it is also feasible to utilize piezoresistive pressure sensors which expand the range further up to approximately three bar. In such a case with a single gas pressure measuring cell configuration a range from vacuum up to overpressure of a few bar can be covered. A further advantage of the introduced gas pressure measuring cell configuration lies in its calibration. Both sensor types must be calibrated and this can be carried out more simply in the present configuration since the temperature behaviour in the present configuration has high synchronization characteristics of the involved components and the configuration is compact. For this reason it is now also feasible to realize a permanent field calibration, for example by acquiring value sets of pressure-temperature which can subsequently be compared automatically.

1. Gas pressure measuring cell configuration with a thermal conduction vacuum cell according to Pirani (Pi), comprising a measuring chamber housing (3) enclosing a measuring chamber (2) and with a measuring connection (4) which channels the gas pressure P to be measured into the measuring chamber (2), wherein in the measuring chamber (2) a heatable measuring filament (1) is disposed connected to an electronic measuring circuitry (11), characterized in that the electronic measuring circuitry (11) is disposed in thermal contact on one side of an insulating carrier plate (10), and the carrier plate (10) forms on the opposite side a component of the measuring chamber housing (3), wherein the measuring filament (1) in series with a measuring resistor (Rm) is supplied directly by the electronic measuring circuitry (11) in feedback and wherein the electronic measuring circuitry (11) directly determines the resistance of the measuring filament (1).

2. Configuration as in claim 1, characterized in that the electronic measuring circuitry (11) comprises a processor (μC) and that the processor (μC) supplies across a digital/analog converter (DAC1) the measuring filament (1), and that the measuring resistor (Rm) and the measuring filament (1) are each connected such that they communicate, across an analog/digital converter (ADC1, 2), with the processor (μC) whereby a feedback circuit is formed and the gas pressure to be measured is determined.

3. Configuration as claimed in claim 2, characterized in that the temperature of the measuring filament (1) as a function of the measured conditions is freely settable.

4. Configuration as claimed in claim 1, characterized in that the carrier plate (10) is a ceramic, preferably an aluminum oxide ceramic.

5. Configuration as in claim 1, characterized in that the electronic measuring circuitry (11) is applied directly on the carrier plate (10) in the form of a thin film circuit, a printed circuit and/or preferably as a thick film circuit.

6. Configuration as in claim 5, characterized in that the circuit is implemented as a hybrid circuit and can include further structural components, such as SMD.

7. Configuration as in claim 1, characterized in that in the proximity of the electronic measuring circuitry (11) on the carrier plate (10) and in thermal contact therewith, a temperature sensor (Tr) is provided for the acquisition of a reference temperature which sensor is connected across an ADC (ADC3) with the processor (μC).

8. Configuration as in claim 1, characterized in that on the carrier plate (10) in the proximity of the electronic measuring circuitry (11) a piezoresistive semiconductor pressure sensor (20), preferably comprising a silicon membrane (24), is applied under seal and that in the carrier plate (10) a port is provided as a connection duct (26) which communicatingly connects the measuring chamber (2) with the piezoresistive pressure sensor (20), wherein the signal output, for its direct signal analysis, of the piezoresistive pressure sensor (20) is connected across a further ADC (ADC4) with the processor (μC).

9. Configuration as in claim 8, characterized in that the resistance values of the piezoresistive semiconductor pressure sensor (20) are additionally analyzed by the processor (μC) as temperature sensor for the measurement of the temperature of the carrier plate (10).

10. Configuration as in claim 8, characterized in that (temperature coefficient) signals of the integrated diode (D1), of the piezo-resistive semiconductor pressure sensor (20) as temperature sensor, are analyzed by the processor (μC) for the measurement of the temperature of the carrier plate (10).

11. Configuration as in claim 8, characterized in that the carrier plate (10) has a thickness in the range of 0.5 mm to 5.0 mm, preferably in the range of 0.6 mm to 2.0 mm.

12. Configuration as in claim 8, characterized in that the carrier plate (10) has a diameter in the range of 10.0 mm to 50.0 mm, preferably in the range of 15 mm to 35 mm.

13. Configuration as in claim 8, characterized in that the measuring filament (1) is implemented as a metal coil, preferably comprising tungsten or nickel, and has a filament length in the range of 10.0 mm to 40.0 mm, preferably in the range of 12.0 mm to 25 mm.
